(19) United States
(12) Patent Application Publication
(10) Pub. No.: US 2025/0192012 A1
(43) Pub. Date: Jun. 12, 2025

(54) SEMICONDUCTOR PACKAGE

(71) Applicant: Samsung Electronics Co., Ltd., Suwon-si (KR)

(72) Inventors: Hongwon KIM, Suwon-si (KR); Dongwon KANG, Suwon-si (KR)

(73) Assignee: Samsung Electronics Co., Ltd., Suwon-si (KR)

(21) Appl. No.: 18/779,786

(22) Filed: Jul. 22, 2024

(30) Foreign Application Priority Data
Dec. 6, 2023 (KR) 10-2023-0175963

(51) Int. Cl. H01L 23/498; H01L 23/495

(52) U.S. Cl. CPC H01L 23/49816; H01L 23/49589

(57) ABSTRACT

A semiconductor package including a redistribution line structure; a semiconductor chip on a first surface of the redistribution line structure; an under-bump structure that on a second surface of the redistribution line structure opposite to the first surface, the under-bump structure including a passivation layer and a conductive pattern layer; an electronic component above the under-bump structure; and an underfill member filling a space between the under-bump structure and the electronic component. The conductive pattern layer is spaced apart from one side surface of the electronic component in plan view and includes a bleeding prevention pattern. The bleeding prevention pattern includes at least one dam region that blocks the underfill member bleeding from the one side surface of the electronic component. The passivation layer includes at least one trench adjacent to the at least one dam region.

### CROSS-REFERENCE TO RELATED APPLICATION

This application claims priority under 35 U.S.C. § 119 to and the benefit of Korean Patent Application No. 10-2023-0175963 filed at the Korean Intellectual Property Office on Dec. 6, 2023, the entire contents of which are incorporated herein by reference.

### BACKGROUND

The present disclosure relates to semiconductor packages.

As electronic devices are required to be down-sized, thinner, lighter, and more functional, various technologies are being researched to improve performance, integration, reliability, or the like of semiconductor packages.

If an electronic component is attached to the semiconductor package using solder balls and surface mount technology (SMT) to improve performance of a semiconductor chip, an underfill process is usually accompanied to improve reliability of the electronic component. An underfill material may bleed to the outside of the electronic component, so that problems such as poor mounting of the electronic component and poor connection reliability of the solder ball may occur.

Therefore, a new semiconductor package structure that may control the bleeding of the underfill material is required.

### SUMMARY

Embodiments of the inventive concepts provide a semiconductor package capable of controlling bleeding of an underfill material and a manufacturing method for the same.

Some example embodiments of the inventive concepts provide a semiconductor package that includes a redistribution line structure; a semiconductor chip on a first surface of the redistribution line structure; an under-bump structure on a second surface of the redistribution line structure opposite the first surface, the under-bump structure including a passivation layer and a conductive pattern layer; an electronic component above the under-bump structure; and an underfill member filling a space between the under-bump structure and the electronic component. The conductive pattern layer is spaced apart from one side surface of the electronic component in plan view, and the conductive pattern layer includes a bleeding prevention pattern. The bleeding prevention pattern includes at least one dam region that blocks bleeding of the underfill member from the one side surface of the electronic component. The passivation layer defines at least one trench therein adjacent to the at least one dam region.

Some example embodiments of the inventive concepts further provide a semiconductor package that includes a redistribution line structure; a semiconductor chip on a first surface of the redistribution line structure; an under-bump structure on a second surface of the redistribution line structure opposite the first surface, the under-bump structure including a passivation layer and a conductive pattern layer; an electronic component above the under-bump structure; and an underfill member filling a space between the under-bump structure and the electronic component. The conductive pattern layer includes a bleeding prevention pattern surrounding the electronic component, the bleeding prevention pattern including a plurality of dam regions spaced apart from each other along a direction extending away from one side surface of the electronic component in plan view. The plurality of dam regions are at a region adjacent the one side surface of the electronic component. The plurality of dam regions block bleeding of the underfill member from the one side surface of the electronic component. The passivation layer defines at least one trench therein between the plurality of dam regions.

Some example embodiments of the inventive concepts still further provide a semiconductor package that includes a redistribution line structure; a semiconductor chip on a first surface of the redistribution line structure; an under-bump structure on a second surface of the redistribution line structure opposite the first surface, the under-bump structure including a passivation layer and a conductive pattern layer, the conductive pattern layer including a bleeding prevention pattern, at least one first conductive pad, and second conductive pads; an electronic component above the at least one first conductive pad; an underfill member filling a space between the first conductive pad and the electronic component; and conductive bumps on the second conductive pads. The bleeding prevention pattern is at a region adjacent to one side surface of the electronic component, the second conductive pads are at regions adjacent to remaining side surfaces of the electronic component other than the one side surface, and the passivation layer defines a trench therein adjacent to the bleeding prevention pattern in plan view.

According to aspects of the inventive concepts, a semiconductor package capable of controlling bleeding of an underfill material and a manufacturing method for the same may be provided.

### BRIEF DESCRIPTION OF THE DRAWINGS

FIG. 1 is a cross-sectional view of a semiconductor package according to some example embodiments of the inventive concepts.

FIG. 2 is a lower view of a region A of the semiconductor package of FIG. 1.

FIG. 3 is a plan view of the region A of the semiconductor package of FIG. 1 viewed from a level at which a conductive pattern layer is disposed.

FIG. 4 is an enlarged view of the region A of FIG. 1.

FIGS. 5, 6, 7, 8, 9, 10 and 11 show other example shapes that a bleeding prevention pattern and a trench may have based on a region B of FIG. 2.

FIGS. 12, 13, 14, 15, 16, 17, 18, 19, 20, 21, 22, 23, 24, 25, 26, 27 and 28 are manufacturing process views for manufacturing a semiconductor package according to some example embodiments of the inventive concepts.

### DETAILED DESCRIPTION

The inventive concepts will be described more fully hereinafter with reference to the accompanying drawings, in which some example embodiments are shown. As those skilled in the art would realize, the described example embodiments may be modified in various different ways, all without departing from the spirit or scope of the inventive concepts.

In order to clearly describe the inventive concepts, parts or portions that are irrelevant to the description are omitted, and identical or similar constituent elements throughout the specification are denoted by the same reference numerals.

Further, in the drawings, the size and thickness of each element are arbitrarily illustrated for ease of description, and the inventive concepts are not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

Throughout the specification, when a part is “connected” to another part, it includes not only a case where the part is “directly connected” but also a case where the part is “indirectly connected” with another part in between. In a similar sense, this includes being “physically connected” as well as being “electrically connected”. Unless explicitly described to the contrary, the word “comprise” and variations such as “comprises” or “comprising” will be understood to imply the inclusion of stated elements but not the exclusion of any other elements.

Throughout the specification, it will be understood that when an element such as a layer, film, region, area, or substrate is referred to as being “on” or “above” another element, it may be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

Further, throughout the specification, the phrase “in plan view” or “on a plane” means viewing a target portion from the top, and the phrase “in cross-sectional view” or “on a cross-section” means viewing a cross-section formed by vertically cutting a target portion from the side.

Throughout the specification, sequential numbers such as 1st and 2nd are used to distinguish a certain component from another component that is the same or similar to the same, and are not necessarily intended to refer to a specific component. Accordingly, a component referred to as a first component in a specific portion of the specification may be referred to as a second component in another portion of the specification.

Throughout the specification, a singular reference to a component includes references to a plurality of these components, unless specifically stated to the contrary. For example, “an insulating layer” may be used to mean not only one insulating layer but also a plurality of insulating layers such as two, three, or more insulating layers.

Throughout the specification, references to one surface and the other surface are intended to distinguish different surfaces from each other, and are not necessarily intended to limit it to a specific surface. Accordingly, a surface referred to as one surface in a specific portion of the specification may be referred to as the other surface in another portion of the specification.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

Hereinafter, a semiconductor package according to some example embodiments of the inventive concepts will be described with reference to the drawings.

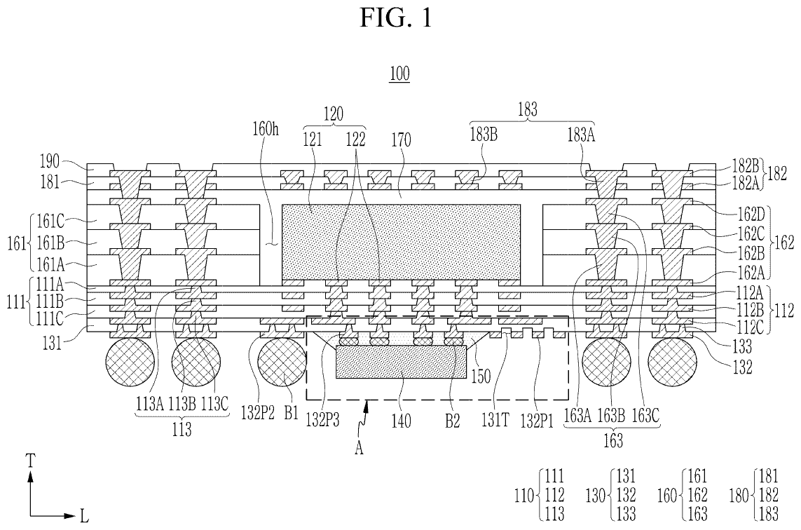

Referring to FIGS. 1 to 4, the semiconductor package 100 according to an some example embodiments of the present disclosure may include a first redistribution line structure 110, a semiconductor chip 120, an under-bump structure 130, an electronic component 140, an underfill member 150, a support substrate 160, a sealant (or an encapsulant) 170, a second redistribution line structure 180, and a passivation layer 190.

The first redistribution line structure 110 may include an insulating layer 111, a redistribution line layer 112, and a via 113. For example, the first redistribution line structure 110 may include a first insulating layer 111A, a first redistribution line layer 112A disposed on the first insulating layer 111A, a first via 113A penetrating the first insulating layer 111A and connecting the first redistribution line layer 112A to the semiconductor chip 120 and a wiring layer 162 of the support substrate 160, a second insulating layer 111B disposed on the first insulating layer 111A to cover the first redistribution line layer 112A, a second redistribution line layer 112B disposed on the second insulating layer 111B, a second via 113B penetrating the second insulating layer 111B to connect the second redistribution line layer 112B to the first redistribution line layer 112A, a third insulating layer 111C disposed on the second insulating layer 111B to cover the second redistribution line layer 112B, a third redistribution line layer 112C disposed on the third insulating layer 111C, and a third via 113C penetrating the third insulating layer 111C to connect the third redistribution line layer 112C to the second redistribution line layer 112B.

The insulating layer 111 may include a photoimageable dielectric (PID). If the insulating layer 111 includes the photoimageable dielectric, the insulating layer 111 with a thin thickness and the via 113 with a fine pitch may be formed. However, the inventive concepts are not limited thereto, and the insulating layer 111 may be a thermosetting resin such as an epoxy resin or the like, a thermoplastic resin such as polyimide or the like, prepreg, an Ajinomoto Build-up Film (ABF), or the like.

The redistribution line layer 112 may redistribute a connection pad 122 of the semiconductor chip 120, and may be electrically connected to the wiring layer 162 of the support substrate 160 and the under-bump structure 130. The redistribution line layer 112 may perform various functions according to a design, and for example, it may include a signal pattern, a power pattern, a ground pattern, and the like.

The via 113B or 113C may penetrate the insulating layer 111 to connect redistribution line layers 112 disposed at different layers. The first via 113A may penetrate the first insulating layer 111A, and may contact the connection pad 122 of the semiconductor chip 120 and/or a first wiring layer 162A of the support substrate 160. As described later, the first redistribution line structure 110 may be formed using a chip-first method after the semiconductor chip 120 is disposed in a through hole 160h of the support substrate 160 and the semiconductor chip 120 and the through hole 160h are sealed with the sealant 170, and through this process, the first via 113A in contact with the connection pad 122 of the semiconductor chip 120 and/or the first wiring layer 162A of the support substrate 160 may be formed.

The via 113 may have various shapes such as a tapered shape having a width narrowing along a thickness direction, a cylindrical shape having a constant width along a thickness direction, and the like.

A conductive material may be used as a material of each of the redistribution line layer 112 and the via 113, and for example, each of the redistribution line layer 112 and the via 113 may include aluminum (Al), copper (Cu), gold (Au), silver (Ag), platinum (Pt), tin (Sn), chromium (Cr), palladium (Pd), lead (Pb), titanium (Ti), or an alloy thereof, but the inventive concepts are not limited thereto.

The redistribution line layer 112 and the via 113 may be integrally formed with each other, so that there is no boundary between them. For example, the redistribution line layer 112 and the via 113 may be integrally formed by forming a via hole in the insulating layer 111, forming a seed layer on a bottom surface and a wall surface of the via hole and the insulating layer 111, and then forming a plating layer on the seed layer.

The semiconductor chip 120 may be disposed on one surface of the first redistribution line structure 110 and in the through hole 160h of the support substrate 160, and may be electrically connected to the redistribution line layer 112 of the first redistribution line structure 110.

The semiconductor chip 120 may include a body 121 and a connection pad 122.

The body 121 may include a semiconductor substrate including silicon (Si), germanium (Ge), gallium arsenide (GaAs), silicon carbide (SiC), a plurality of individual elements, an internal circuit, and an interlayer insulating film.

The connection pad 122 may electrically connect the semiconductor chip 120 to another configuration such as the first redistribution line structure 110 or the like. A material of the connection pad 122 may be a conductive material such as aluminum (Al), copper (Cu), or the like.

As shown in the drawings, the semiconductor chip 120 may be disposed in a face-down direction so that the connection pad 122 faces the first redistribution line structure 110, but the semiconductor chip 120 may be disposed in a face-up direction so that the connection pad 122 faces the second redistribution line structure 180.

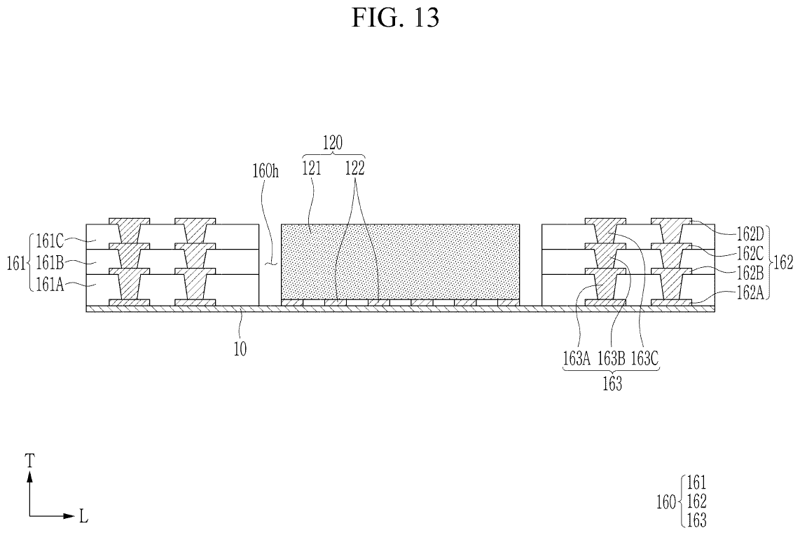

As will be described later, the semiconductor chip 120 may be attached on an adhesive film 10 together with the support substrate 160 (e.g., see FIG. 13), so that one surface of the semiconductor chip 120 is coplanar with one surface of the support substrate 160.

A type of the semiconductor chip 120 is not particularly limited, and the semiconductor chip 120 may be a central processing unit (CPU), a graphics processing unit (GPU), an application processor (AP), a logic chip, a volatile or nonvolatile memory chip, a system on chip (SOC), or the like.

The under-bump structure 130 may be disposed on the other surface that is an opposite surface of the one surface of the first redistribution line structure 110.

The under-bump structure 130 may include a first passivation layer 131 and a conductive pattern layer 132.

The first passivation layer 131 may be disposed on the first redistribution line structure 110 to protect the first redistribution line structure 110 from a physical, chemical, or mechanical damage.

An insulating material (for example, an Ajinomoto Build-up Film (ABF)) may be used as a material of the first passivation layer 131. However, the inventive concepts are not limited thereto, and the first passivation layer 131 may be a thermosetting resin such as an epoxy resin or the like, a thermoplastic resin such as polyimide or the like, prepreg, or the like. Alternatively, a solder resist (SR) may be used as a material of the first passivation layer 131.

The conductive pattern layer 132 may include a bleeding prevention pattern 132P1, a first conductive pad 132P2, and a second conductive pad 132P3.

The bleeding prevention pattern 132P1 may protrude above the first passivation layer 131 to control bleeding of the underfill member 150.

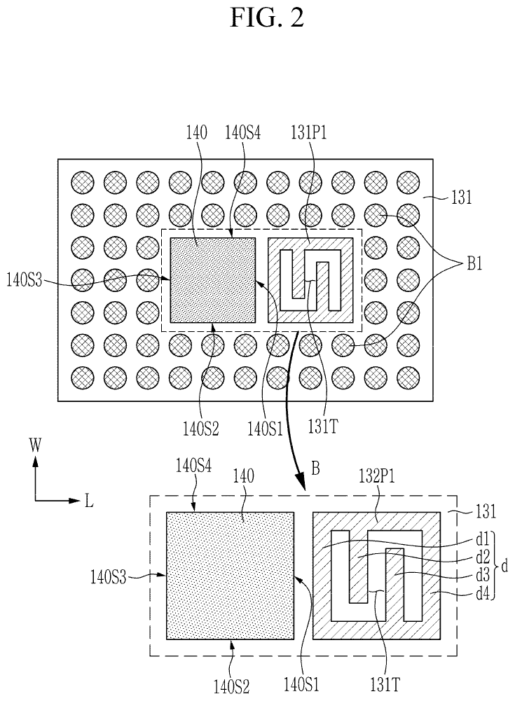

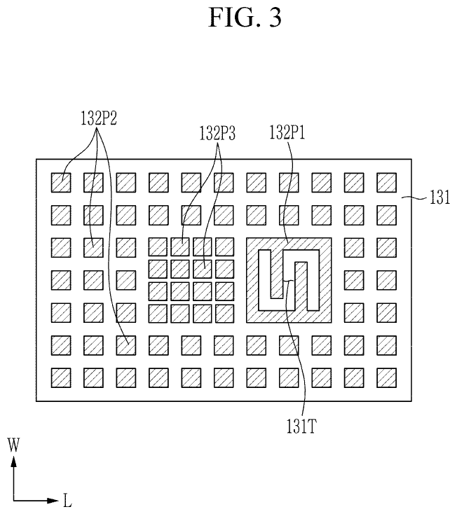

Referring to FIGS. 2 to 4, the bleeding prevention pattern 132P1 may be disposed to be spaced apart from one side surface 140S1 of the electronic component 140 on a plane. For example, the bleeding prevention pattern 132P1 may be disposed to be spaced apart from the one side surface 140S1 of the electronic component 140 in a length direction L on a plane. In order to clearly indicate a position of each configuration, the underfill member 150 is excluded from FIGS. 2 and 3.

The bleeding prevention pattern 132P1 may include at least one dam region d that blocks the one side surface 140S1 of the electronic component 140. An underfill material UF forming the underfill member 150 may be injected (or implanted) between the under-bump structure 130 and the electronic component 140 through a space between the one side surface 140S1 of the electronic component 140 and the bleeding prevention pattern 132P1, and the bleeding prevention pattern 132P1 may limit and/or prevent the underfill material UF from bleeding in an outward direction of the electronic component 140, improving reliability of the semiconductor package 100. For example, the bleeding prevention pattern 132P1 may block the underfill material UF bleeding in an outward direction from the one side surface 140S1 of the electronic component.

In some example embodiments, the bleeding prevention pattern 132P1 may include a plurality of dam regions d1, d2, d3, and d4 spaced apart from each other in a direction away from the one side surface 140S1 of the electronic component 140. Referring to the drawings, the plurality of dam regions d1, d2, d3, and d4 may be spaced apart from each other in the length direction L. For example, the bleeding prevention pattern 132P1 may include the first dam region d1, the second dam region d2, the third dam region d3, and the fourth dam region d4 that are sequentially spaced apart from each other along the length direction L. Bleeding of the underfill material UF that is not controlled through the dam region disposed closer to the electronic component 140 and overflows may be further limited and/or prevented through the plurality of dam regions d1, d2, d3, and d4.

The plurality of dam regions d1, d2, d3, and d4 may be a configuration for describing regions of the bleeding prevention pattern 132P1 that are spaced apart from each other to block the one side surface 140S1 of the electronic component 140, and may not have a boundary between each other. Two or more of the plurality of dam regions d1, d2, d3, and d4 may be connected to each other through other regions of the bleeding prevention pattern 132P1.

The bleeding prevention pattern 132P1 may be disposed only in a region adjacent to the one side surface 140S1 of the electronic component 140, and the first conductive pad 132P2 may be disposed at a region adjacent to the remaining side surface 140S2, 140S3, or 140S4 except for the one side surface 140S1. By disposing the bleeding prevention pattern 132P1 only in the region adjacent to the one side surface 140S1 of the electronic component 140 into which the underfill material UF is injected, the bleeding of the underfill material UF may be limited and/or prevented, and a sufficient space for disposing the first conductive pad 132P2 at the region adjacent to the remaining side surface 140S2, 140S3, or 140S4 may be secured.

The first passivation layer 131 may include at least one trench 131T adjacent to the dam region d of the bleeding prevention pattern 132P1 in order to control bleeding of the underfill member 150 together with the bleeding prevention pattern 132P1. For example, the first passivation layer 131 may define at least one trench 131T therein. The trench 131T may penetrate at least a portion of the first passivation layer 131 in a thickness direction T, and may further limit and/or prevent bleeding of the underfill material UF that is not controlled through the dam region d and overflows, further improving reliability of the semiconductor package 100. For example, the overflow underfill material UF may enter and/or fill the trench 131T and may be limited and/or prevented from flowing to other portions on the passivation layer 131, further improving reliability of the semiconductor package 100.

In some example embodiments, the trench 131T may be a single trench 131T including regions each positioned between the plurality of dam regions d1, d2, d3, and d4. For example, as shown in FIG. 2, the trench 131T may be the single trench 131T including a region positioned between the first dam region d1 and the second dam region d2, a region positioned between the second dam region d2 and the third dam region d3, and a region positioned between the third dam region d3 and the fourth dam region d4. The region disposed between the plurality of dam regions d1, d2, d3, and d4 of the trench 131T may further limit and/or prevent bleeding of the underfill material UF that overflows without being controlled through each of the first dam region d1, the second dam region d2, and the third dam region d3.

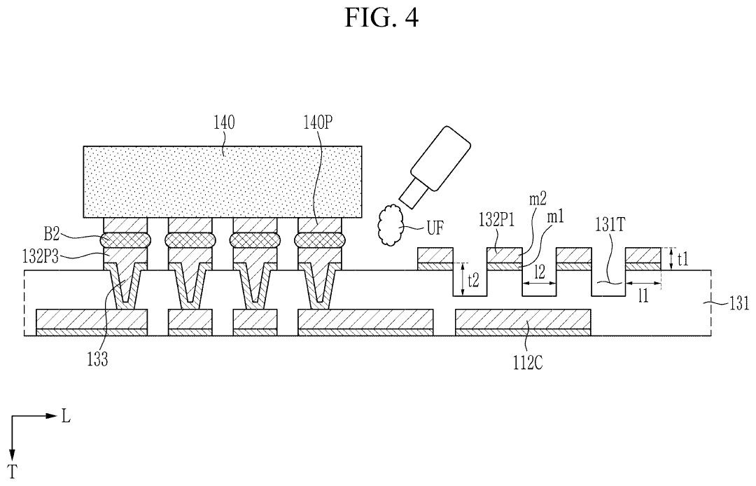

Referring to FIG. 4, the bleeding prevention pattern 132P1 may include a first metal layer m1 and a second metal layer m2 disposed on the first metal layer m1. The first metal layer m1 may be a seed layer formed on the first passivation layer 131 by electroless plating or the like, and the second metal layer m2 may be a plating layer formed by electroplating or the like. The bleeding prevention pattern 132P1 may be formed together with the first conductive pad 132P2 and the second conductive pad 132P3 through a photolithography process, and may include the first metal layer m1 and the second metal layer m2 through the photolithography process.

A length l1 of the dam region d may be about 1 μm or more and 10 μm or less. In the present specification, the length may mean a length along the length direction L from the one side surface 140S1 of the electronic component 140 to the dam region d. As described above, the bleeding prevention pattern 132P1 may be formed together with the first conductive pad 132P2 and the second conductive pad 132P3 through the photolithography process, so that the length of the dam region d is finely formed in microns. However, if the length l1 of the dam region d becomes longer, a space for disposing the first conductive pad 132P2 and the second conductive pad 132P3 may decrease, so the length l1 of the dam region d may be about 10 μm or less.

A thickness t1 of the bleeding prevention pattern 132P1 may be about 1 μm or more and 15 μm or less. A thickness of the dam region d may be about 1 μm or more and 15 μm or less. In the present specification, the thickness may mean a thickness along the thickness direction T. If the thickness t1 of the bleeding prevention pattern 132P1 is too thin, it may be difficult to prevent the bleeding of the underfill material. If the thickness t1 of the bleeding prevention pattern 132P1 is too thick, the semiconductor package 100 may become thick and the plating process may become complicated. Therefore, the thickness t1 of the bleeding prevention pattern 132P1 may be controlled within the above-described range.

A length l2 of the trench 131T between the plurality of dam regions d1, d2, d3, and d4 may be about 1 μm or more and 10 μm or less. The trench 131T may be finely formed by forming the bleeding prevention pattern 132P1 patterned through the photolithography process to have the plurality of dam regions d1, d2, d3, and d4 and performing a laser processing on a space between the plurality of dam regions d1, d2, d3, and d4. However, if the length l2 of the trench 131T becomes longer, the space for disposing the first conductive pad 132P2 and the second conductive pad 132P3 may decrease, so that the length l2 of the trench 131T may be 10 μm or less.

A depth t2 of the trench 131T may be about 1 μm or more and 10 μm or less. In the present specification, the depth may mean a depth along the thickness direction T. If the depth t2 of the trench 131T is too shallow, it may be difficult to prevent the bleeding of the underfill material, and if the depth t2 of the trench 131T is too deep, an increase in a thickness of a passivation layer 181 may be accompanied. Therefore, the depth t2 of the trench 131T may be controlled within the above-described range.

Each of the first conductive pad 132P2 and the second conductive pad 132P3 may be disposed on the first passivation layer 131 to be spaced apart from the bleeding prevention pattern 132P1.

A first conductive bump B1 such as a solder ball for physically and electrically connecting the semiconductor package 100 to another configuration such as a main board or the like may be disposed on the first conductive pad 132P2. For example, the first conductive pad 132P2 may increase connection reliability between the first redistribution line structure 110 and the first conductive bump B1. In a technical field to which the inventive concepts belongs, the first conductive pad 132P2 may be referred to as an under-bump pad, an under-bump metal, or the like.

The electronic component 140 may be disposed above the second conductive pad 132P3, and a second conductive bump B2 for physically and electrically connecting the second conductive pad 132P3 and the electronic component 140 may be disposed between the second conductive pad 132P3 and the electronic component 140. The second conductive bump B2 may be disposed between the second conductive pad 132P3 and the electronic component 140 to be covered with the underfill member 150.

The bleeding prevention pattern 132P1, the first conductive pad 132P2, and the second conductive pad 132P3 may be formed through the same process, so that the bleeding prevention pattern 132P1, the first conductive pad 132P2, and the second conductive pad 132P3 may be disposed at the same level on the first passivation layer 131.

Like the bleeding prevention pattern 132P1, the first conductive pad 132P2 and the second conductive pad 132P3 may include the first metal layer m1 and the second metal layer m2 disposed on the first metal layer m1.

A conductive material may be used as a material of each of the bleeding prevention pattern 132P1, the first conductive pad 132P2, and the second conductive pad 132P3, and for example, each of the bleeding prevention pattern 132P1, the first conductive pad 132P2, and the second conductive pad 132P3 may include copper (Cu), aluminum (Al), nickel (Ni), titanium (Ti), chromium (Cr), or an alloy thereof, but the inventive concepts are not limited thereto.

The under-bump structure 130 may further include a via 133 that physically and electrically connects the first conductive pad 132P2 and the second conductive pad 132P3 to the redistribution line layer 112. The first conductive pad 132P2, the second conductive pad 132P3, and the via 133 may be integrally formed with each other, so that there is no boundary between them.

The electronic component 140 may be disposed above the under-bump structure 130.

The electronic component 140 may be a surface mount component mounted above the under-bump structure 130 using a surface mount technology (SMT). For example, the electronic component 140 may be a passive element such as a capacitor (e.g., an integrated stacked capacitor (ISC)), an inductor, or the like. As is known, the integrated stack capacitor may include a plurality of trenches including a plurality of metal layers that store an electric charge and an insulating layer disposed between the plurality of metal layers. If the electronic component 140 is the integrated stacked capacitor, the electronic component 140 may provide excellent capacity and performance, high reliability, and design flexibility.

The underfill member 150 may fill a space between the under-bump structure 130 and the electronic component 140. The underfill member 150 may secure reliability of the electronic component 140 by relieving a stress applied to the second conductive bump B2 due to a difference in a coefficient of thermal expansion between configurations or a physical impact and preventing a defect resulting from the difference in the coefficient of thermal expansion between the configurations or the physical impact.

A material of the underfill member 150 may be based on a thermosetting resin such as an epoxy resin, and may include a silica filler. For example, the underfill member 150 may be formed by injecting the underfill material into the space between the under-bump structure 130 and the electronic component 140 through a nozzle or the like (e.g., see FIG. 4) and curing the underfill material.

Like the semiconductor chip 120, the support substrate 160 may be disposed on the one surface of the first redistribution line structure 110, and may include the through hole 160h.

The through hole 160h may penetrate the support substrate 160 in the thickness direction T, and the semiconductor chip 120 may be disposed in the through hole 160h.

The support substrate 160 may include an insulating layer 161, a wiring layer 162, and a via 163. For example, the support substrate 160 may include the first wiring layer 162A, a first insulating layer 161A covering the first wiring layer 162A, a second wiring layer 162B disposed on the first insulating layer 161A, a first via 163A penetrating the first insulating layer 161A to connect the first wiring layer 162A and the second wiring layer 162B, a second insulating layer 161B disposed on the first insulating layer 161A to cover the second wiring layer 162B, a third wiring layer 162C disposed on the second insulating layer 161B, a second via 163B penetrating the second insulating layer 161B to connect the second wiring layer 162B and the third wiring layer 162C, a third insulating layer 161C disposed on the second insulating layer 161B to cover the third wiring layer 162C, a fourth wiring layer 162D disposed on the third insulating layer 161C, and a third via 163C penetrating the third insulating layer 161C to connect the third wiring layer 162C and the fourth wiring layer 162D.

An insulating material may be used as a material of the insulating layer 161, and for example, the insulating layer 161 may be a thermosetting resin such as an epoxy resin or the like, a thermoplastic resin such as polyimide or the like, prepreg, an Ajinomoto Build-up Film (ABF), or the like. The insulating layer 161 may include a reinforcing material such as an inorganic filler or a glass fiber.

The insulating layer 161 may have a thicker thickness than those of the insulating layer 111 of the first redistribution line structure 110 and an insulating layer 181 of the second redistribution line structure 180. Accordingly, rigidity of the support substrate 160 may be increased and warpage of the support substrate 160 may be controlled.

The wiring layer 162 may be electrically connected to the redistribution line layer 112 of the first redistribution line structure 110 and a redistribution line layer 182 of the second redistribution line structure 180.

The support substrate 160 may have an embedded trace substrate (ETS) structure, and for example, a circuit pattern included in the first wiring layer 162A disposed at a lowermost side of the wiring layer 162 may have a structure of a buried pattern buried within the first insulating layer 161A. If the support substrate 160 has the ETS structure, a fine circuit may be implemented so that the number of wiring layers is reduced and the circuit line width is finely controlled.

The via 163 may penetrate the insulating layer 161 to connect wiring layers 162 disposed at different layers.

The via 163 may have various shapes such as a tapered shape having a width narrowing along a thickness direction, a cylindrical shape having a constant width along a thickness direction, and the like.

A conductive material may be used as a material of each of the wiring layer 162 and the via 163, and for example, each of the wiring layer 162 and the via 163 may include aluminum (Al), copper (Cu), gold (Au), silver (Ag), platinum (Pt), tin (Sn), chromium (Cr), palladium (Pd), lead (Pb), titanium (Ti), or an alloy thereof, but the inventive concepts are not limited thereto.

The wiring layer 162 and the via 163 may be integrally formed with each other, so that there is no boundary between them. For example, the wiring layer 162 and the via 163 may be integrally formed by forming a via hole in the insulating layer 161, forming a seed layer on a bottom surface and a wall surface of the via hole and the insulating layer 161, and then forming a plating layer on the seed layer.

The sealant 170 may fill at least a portion of the through hole 160h, and may seal the semiconductor chip 120. The sealant 170 may extend on the support substrate 160 to cover an upper surface of the support substrate 160 along with an upper surface of the semiconductor chip 120. The sealant 170 may be formed of a thermosetting resin such as an epoxy molding compound (EMC) or an epoxy resin, but the inventive concepts are not limited thereto.

The second redistribution line structure 180 may be disposed on the sealant 170. The second redistribution line structure 180 may be electrically connected to the wiring layer 162 of the support substrate 160, and may electrically connect the semiconductor package 100 to another configuration disposed at an upper side of the semiconductor package 100.

The second redistribution line structure 180 may include the insulating layer 181, the redistribution line layer 182, and a via 183. For example, the second redistribution line structure 180 may include a first redistribution line layer 182A disposed on the sealant 170, the insulating layer 181 disposed on the sealant 170 to cover the first redistribution line layer 182A, a second redistribution line layer 182B disposed on the insulating layer 181, a first via 183A penetrating the insulating layer 181 and the sealant 170 to connect the second redistribution line layer 182B to the fourth wiring layer 162D of the support substrate 160, and a second via 183B penetrating the insulating layer 181 to connect the second redistribution line layer 182B to the first redistribution line layer 182A.

An insulating material (for example, an Ajinomoto Build-up Film (ABF)) may be used as a material of the insulating layer 181. However, the inventive concepts are not limited thereto, and the insulating layer 181 may be a thermosetting resin such as an epoxy resin or the like, a thermoplastic resin such as polyimide or the like, prepreg, or the like.

The redistribution line layer 182 may be connected to the wiring layer 162 of the support substrate 160 to redistribute the wiring layer 162. The redistribution line layer 182 may perform various functions according to a design, and for example, it may include a signal pattern, a power pattern, a ground pattern, and the like.

The via 183 may penetrate the insulating layer 181 to connect redistribution line layers 182 disposed at different layers, or may penetrate the sealant 170 to connect the wiring layer 162 and the redistribution line layer 182. As shown in the drawings, the first redistribution line layer 182A may be connected to the fourth wiring layer 162D of the support substrate 160 through the first via 183A along with the second redistribution line layer 182B, but the first redistribution line layer 182A may be connected to the fourth wiring layer 162D through a via (not shown) penetrating only the sealant 170.

The via 183 may have various shapes such as a tapered shape having a width narrowing along a thickness direction, a cylindrical shape having a constant width along a thickness direction, and the like.

A conductive material may be used as a material of each of the redistribution line layer 182 and the via 183, and for example, each of the redistribution line layer 182 and the via 183 may include aluminum (Al), copper (Cu), gold (Au), silver (Ag), platinum (Pt), tin (Sn), chromium (Cr), palladium (Pd), lead (Pb), titanium (Ti), or an alloy thereof, but the inventive concepts are not limited thereto.

The redistribution line layer 182 and the via 183 may be integrally formed with each other, so that there is no boundary between them. For example, the redistribution line layer 182 and the via 183 may be integrally formed by forming a via hole in the insulating layer 181, forming a seed layer on a bottom surface and a wall surface of the via hole and the insulating layer 181, and then forming a plating layer on the seed layer.

The semiconductor package 100 may further include a second passivation layer 190 that is disposed on the second redistribution line structure 180 to protect the second redistribution line structure 180 from a physical, chemical, or mechanical damage. The second passivation layer 190 may have an opening that exposes at least a portion of the redistribution line layer 182.

An insulating material (for example, an Ajinomoto Build-up Film (ABF)) may be used as a material of the second passivation layer 190. However, the inventive concepts are not limited thereto, and the second passivation layer 190 may be a thermosetting resin such as an epoxy resin or the like, a thermoplastic resin such as polyimide or the like, prepreg, or the like. Alternatively, a solder resist (SR) may be used as a material of the second passivation layer 190.

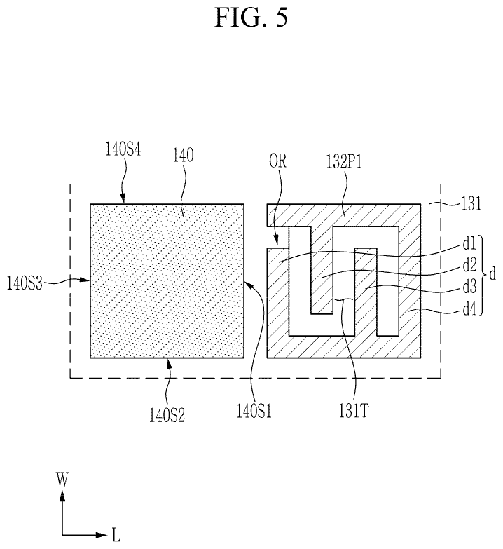

FIG. 5 shows another example shape that the bleeding prevention pattern and the trench may have.

In some example embodiments, the first passivation layer 131 may include a region OR exposed through the bleeding prevention pattern 132P1 so that it includes a region extending from a region adjacent to the one side surface 140S1 of the electronic component 140 to the trench 131T adjacent to the first dam region d1 on a plane. Accordingly, the underfill material bleeding to the outside of the electronic component 140 may flow into the trench 131T along the region OR exposed through the bleeding prevention pattern 132P1 of the first passivation layer 131.

At least one side portion of both side portions in a width direction W of the exposed region OR of the first passivation layer 131 may be adjacent to the bleeding prevention pattern 132P1. For example, as shown in the drawings, the both side portions of the exposed region OR of the first passivation layer 131 may be adjacent to the bleeding prevention pattern 132P1, and for example, one side portion of the both side portions may be adjacent to the first dam region d1.

The trench 131T may be a single trench 131T including regions each positioned between the plurality of dam regions d1, d2, d3, and d4. The single trench 131T may form a flow path for the inflowed underfill material.

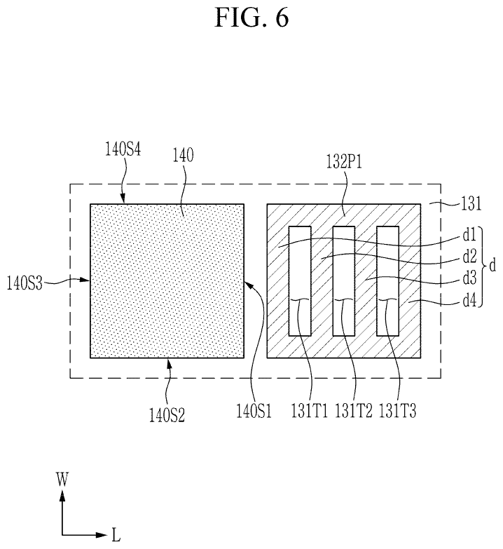

FIG. 6 shows another example shape that the bleeding prevention pattern and the trench may have.

In some example embodiments, the trench 131T may be a plurality of trenches 131T1, 131T2, and 131T3 each positioned between the plurality of dam regions d1, d2, d3, and d4. For example, as shown in the drawings, the trench 131T may include the first trench 131T1 positioned between the first dam region d1 and the second dam region d2, the second trench 131T2 positioned between the second dam region d2 and the third dam region d3, and the third trench 131T3 positioned between the third dam region d3 and the fourth dam region d4.

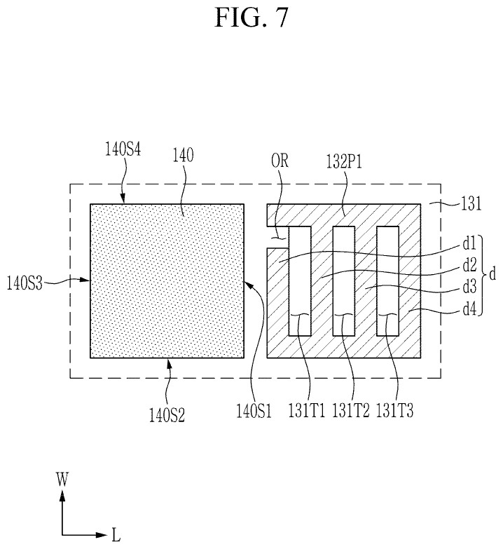

FIG. 7 shows another example shape that the bleeding prevention pattern and the trench may have.

In some example embodiments, the first passivation layer 131 may include a region OR exposed through the bleeding prevention pattern 132P1 so that it includes a region extending from a region adjacent to the one side surface 140S1 of the electronic component 140 to the first trench 131T1 adjacent to the first dam region d1 on a plane. Accordingly, the underfill material bleeding to the outside of the electronic component 140 may flow into the first trench 131T1 along the region OR exposed through the bleeding prevention pattern 132P1 of the first passivation layer 131.

At least one side portion of both side portions in the width direction W of the exposed region OR of the first passivation layer 131 may be adjacent to the bleeding prevention pattern 132P1. For example, as shown in the drawings, the both side portions of the exposed region OR of the first passivation layer 131 may be adjacent to the bleeding prevention pattern 132P1, and one side portion of the both side portions may be adjacent to the first dam region d1.

The trench 131T may be a plurality of trenches 131T1, 131T2, and 131T3 each positioned between the plurality of dam regions d1, d2, d3, and d4.

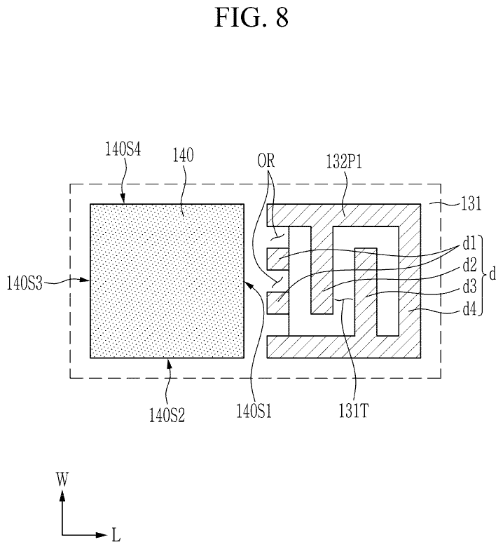

FIG. 8 shows another example shape that the bleeding prevention pattern and the trench may have.

In some example embodiments, the first passivation layer 131 may include a plurality of regions OR exposed through the bleeding prevention pattern 132P1 so that it includes a region extending from a region adjacent to the one side surface 140S1 of the electronic component 140 to the first trench 131T1 adjacent to the first dam region d1 on a plane. Accordingly, the underfill material bleeding to the outside of the electronic component 140 may flow into the first trench 131T1 along the plurality of regions OR exposed through the bleeding prevention pattern 132P1 of the first passivation layer 131.

The first dam region d1 may be a plurality of regions discontinuously disposed along the width direction W. The number of first dam regions d1 is not limited to the number shown in the drawings, and may be changed depending on some example embodiments. A width along the width direction W of each first dam region d1 may also be changed depending on some example embodiments.

At least one side portion of both side portions in the width direction W of the exposed region OR of the first passivation layer 131 may be adjacent to the bleeding prevention pattern 132P1. For example, the both side portions of the exposed region OR of the first passivation layer 131 may be adjacent to the bleeding prevention pattern 132P1, and one side portion of the both side portions may be adjacent to the first dam region d1. A portion of the exposed region OR of the first passivation layer 131 may be disposed between the plurality of first dam regions d1.

The trench 131T may be a single trench 131T including regions each positioned between the plurality of dam regions d1, d2, d3, and d4. However, the inventive concepts are not limited thereto, and the trench 131T may be a plurality of trenches 131T each positioned between the plurality of dam regions d1, d2, d3, and d4.

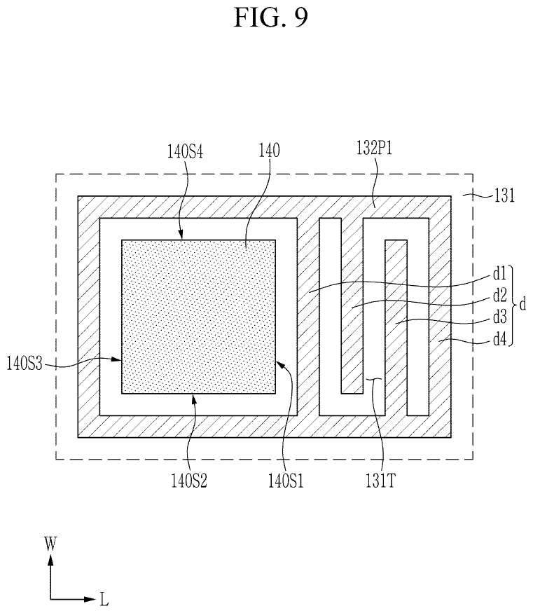

FIG. 9 shows another example shape that the bleeding prevention pattern and the trench may have.

In some example embodiments, the bleeding prevention pattern 132P1 may surround the electronic component 140. For example, the bleeding prevention pattern 132P1 may include the plurality of dam regions d1, d2, d3, and d4 spaced apart from each other in a direction crossing the one side surface 140S1 of the electronic component 140 on a plane at a region blocking the one side surface 140S1 of the electronic component 140. For example, the direction crossing the one side surface 140S1 of the electronic component 140 on the plane may be the length direction L.

The first passivation layer 131 may have at least one trench 131T disposed between the plurality of dam regions d1, d2, d3, and d4. In some example embodiments, the trench 131T may be a single trench 131T including regions each positioned between the plurality of dam regions d1, d2, d3, and d4. For example, as shown in the drawings, the trench 131T may be the single trench 131T including a region positioned between the first dam region d1 and the second dam region d2, a region positioned between the second dam region d2 and the third dam region d3, and a region positioned between the third dam region d3 and the fourth dam region d4.

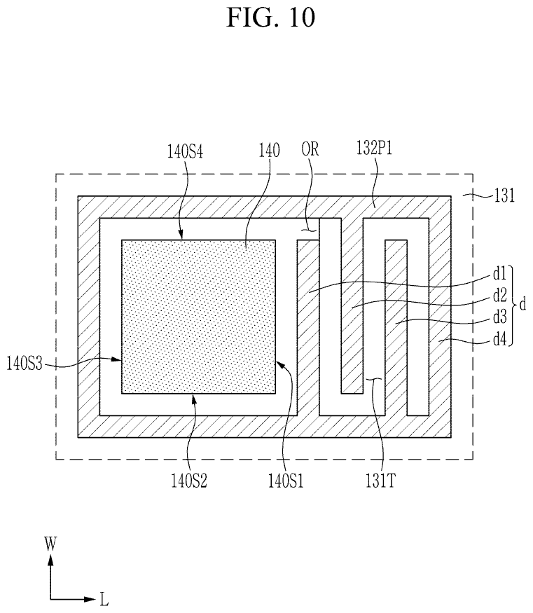

FIG. 10 shows another example shape that the bleeding prevention pattern and the trench may have.

In some example embodiments, compared with the trench shown in FIG. 9, the first passivation layer 131 may include a region OR exposed through the bleeding prevention pattern 132P1 so that it includes a region extending from a region adjacent to the one side surface 140S1 of the electronic component 140 to the trench 131T adjacent to the first dam region d1 on a plane. Accordingly, the underfill material bleeding to the outside of the electronic component 140 may flow into the trench 131T along the region OR exposed through the bleeding prevention pattern 132P1 of the first passivation layer 131.

At least one side portion of both side portions in the width direction W of the exposed region OR of the first passivation layer 131 may be adjacent to the bleeding prevention pattern 132P1. For example, as shown in the drawings, the both side portions of the exposed region OR of the first passivation layer 131 may be adjacent to the bleeding prevention pattern 132P1, and one side portion of the both side portions may be adjacent to the first dam region d1.

The trench 131T may be a single trench 131T including regions each positioned between the plurality of dam regions d1, d2, d3, and d4. However, the inventive concepts are not limited thereto, and the trench 131T may be a plurality of trenches 131T each positioned between the plurality of dam regions d1, d2, d3, and d4.

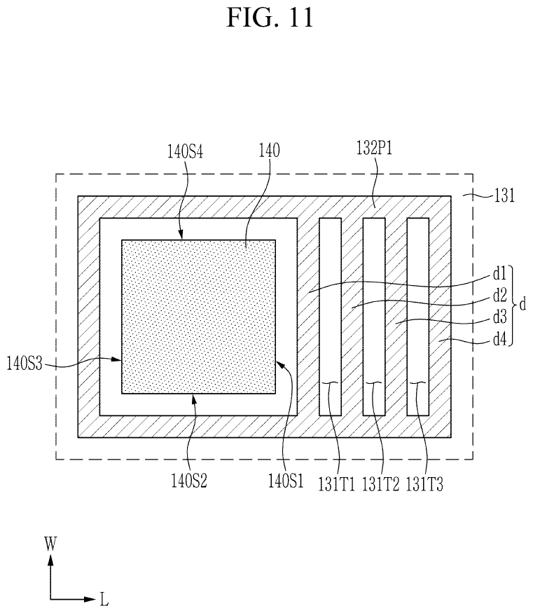

FIG. 11 shows another example shape that the bleeding prevention pattern and the trench may have.

In some example embodiments, compared with the trench shown in FIG. 9, the trench 131T may be a plurality of trenches 131T1, 131T2, and 131T3 each positioned between the plurality of dam regions d1, d2, d3, and d4. For example, as shown in the drawings, the trench 131T may include the first trench 131T1 positioned between the first dam region d1 and the second dam region d2, the second trench 131T2 positioned between the second dam region d2 and the third dam region d3, and the third trench 131T3 positioned between the third dam region d3 and the fourth dam region d4.

Hereinafter, a manufacturing method for the semiconductor package 100 according to some example embodiments of the inventive concepts will be described.

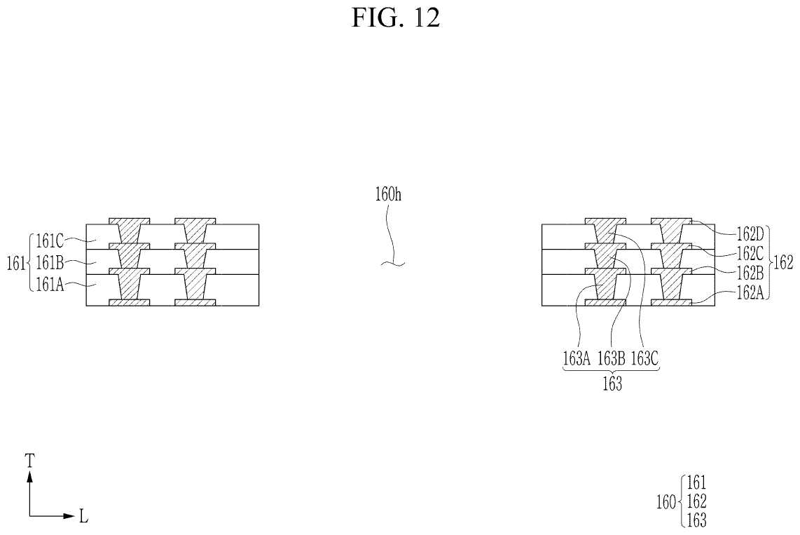

Referring to FIG. 12, first, the support substrate 160 including the through hole 160h may be prepared. For example, the through hole 160h may be formed using a laser drill, a mechanical drill, a sand blast method, or the like.

Next, referring to FIG. 13, the semiconductor chip 120 may be prepared, the support substrate 160 may be disposed on the adhesive film 10, and the semiconductor chip 120 may be disposed in the through hole 160h. For example, the adhesive film 10 may be an adhesive tape whose adhesion is weakened by heat treatment, ultraviolet irradiation, or the like. The semiconductor chip 120 may be disposed in a face-down form so that the connection pad 122 faces the adhesive film 10.

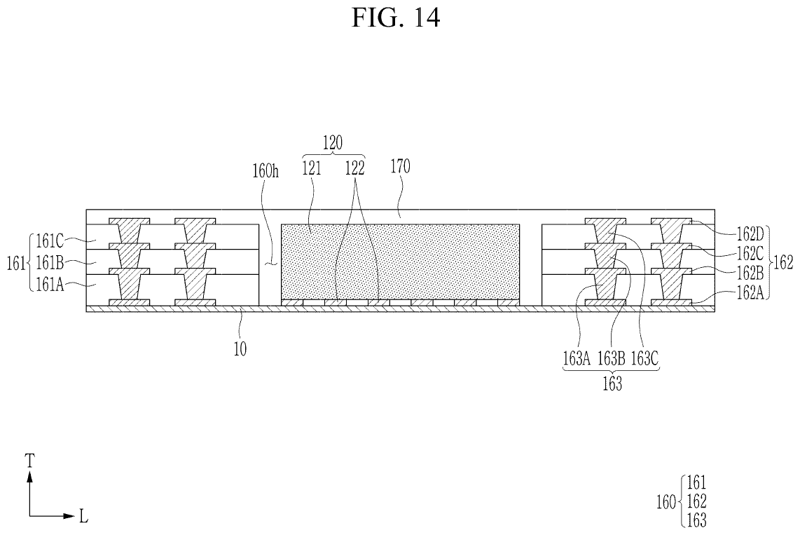

Next, referring to FIG. 14, the semiconductor chip 120 may be sealed with the sealant 170. A process of sealing the semiconductor chip 120 with the sealant 170 may be performed by compression molding, transfer molding, or the like.

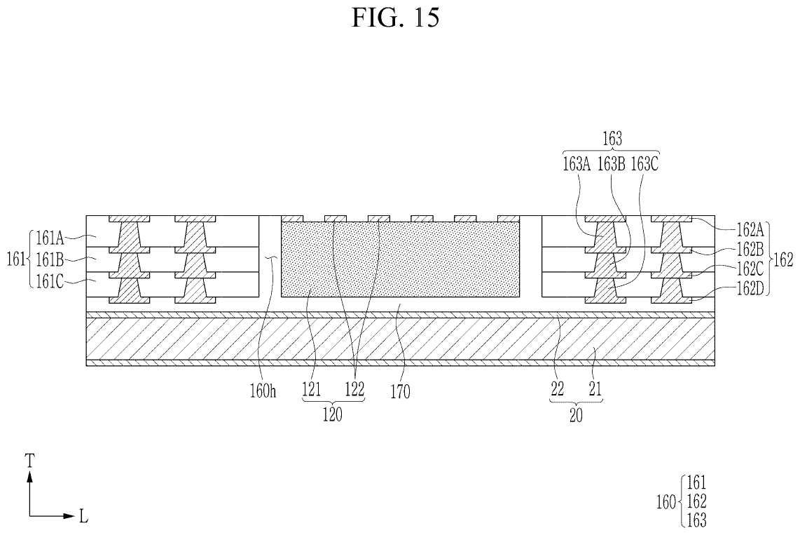

Next, referring to FIG. 15, a first carrier film 20 may be attached on the sealant 170, and the adhesive film 10 may be removed. For example, the first carrier film 20 may be a copper foil laminate such as a DCF including an insulating layer 21 and a metal layer 22 disposed on at least one surface of the insulating layer 21. The adhesive film 10 may be removed by heat treatment, ultraviolet irradiation, or the like.

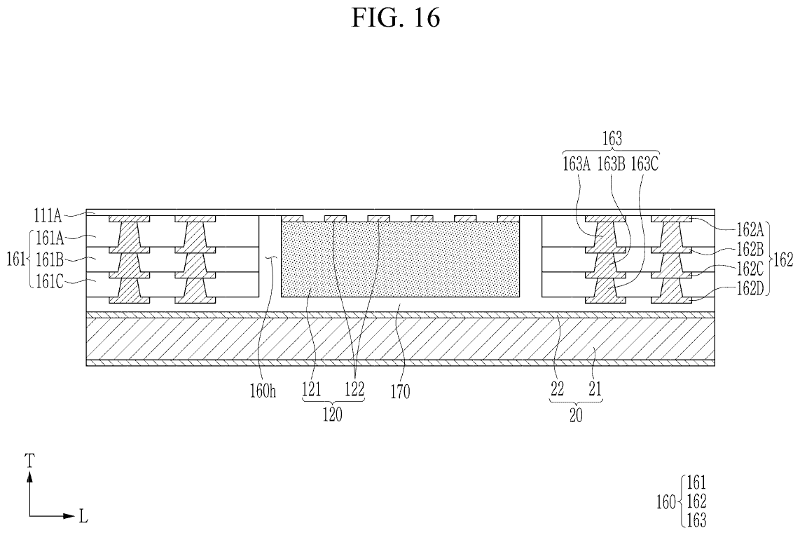

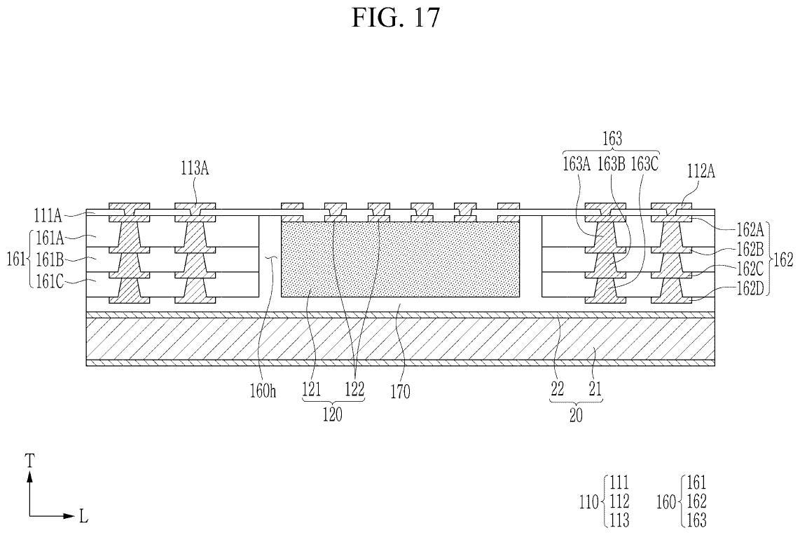

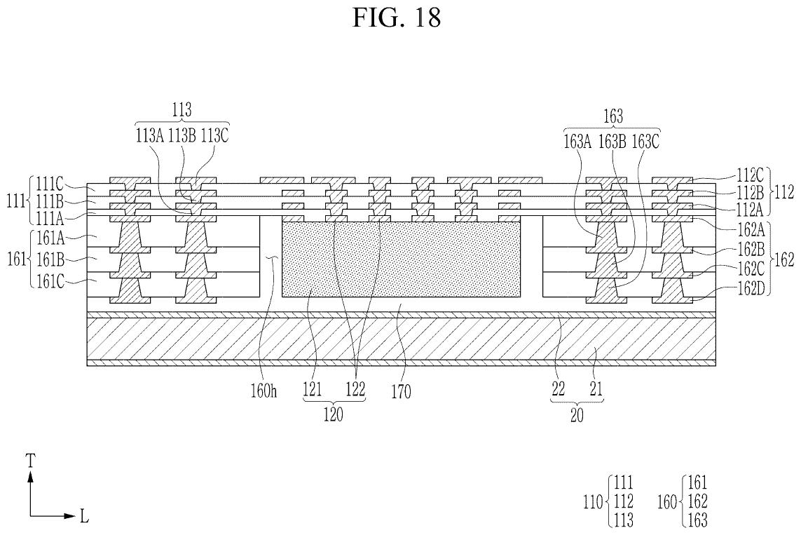

Next, referring to FIGS. 16 to 18, the first redistribution line structure 110 may be formed by repeatedly forming the insulating layer 111, the redistribution line layer 112, and the via 113 on the semiconductor chip 120 and the support substrate 160. The insulating layer 111, the redistribution line layer 112, and the via 113 may be formed by coating a photosensitive insulating material, forming a via hole exposing the connection pad 122 and the wiring layer 162A through exposure and development processes, and then forming the redistribution line layer 112 and the via 113. The redistribution line layer 112 may be electrically connected to the semiconductor chip 120 and the wiring layer 162A through the via 113.

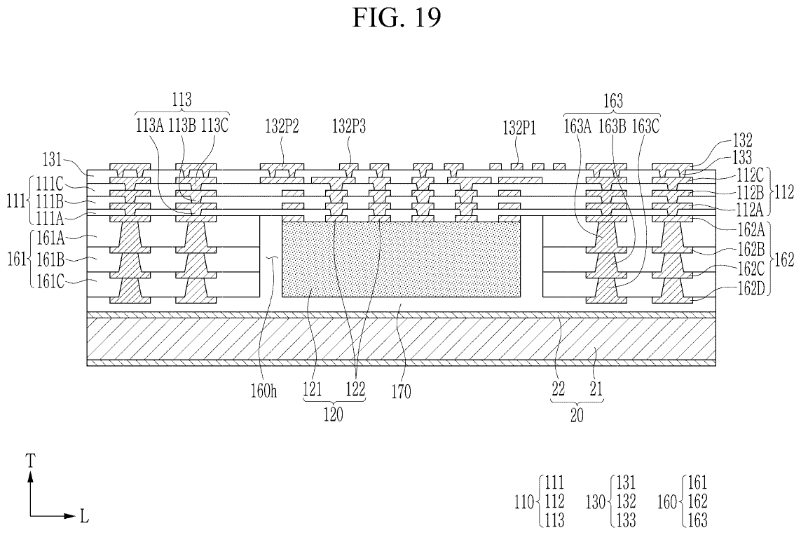

Next, referring to FIG. 19, the first passivation layer 131 may be formed by laminating an insulating material on the first redistribution line structure 110, and the conductive pattern layer 132 and the via 133 may be formed on the first passivation layer 131.

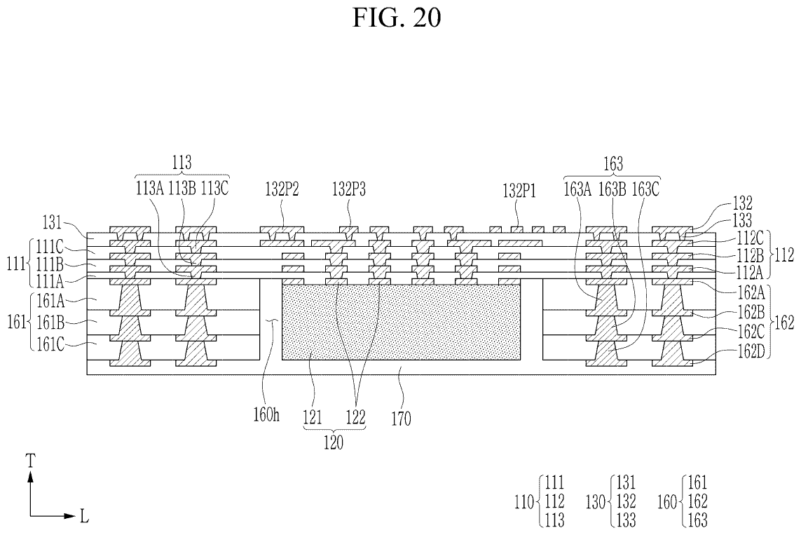

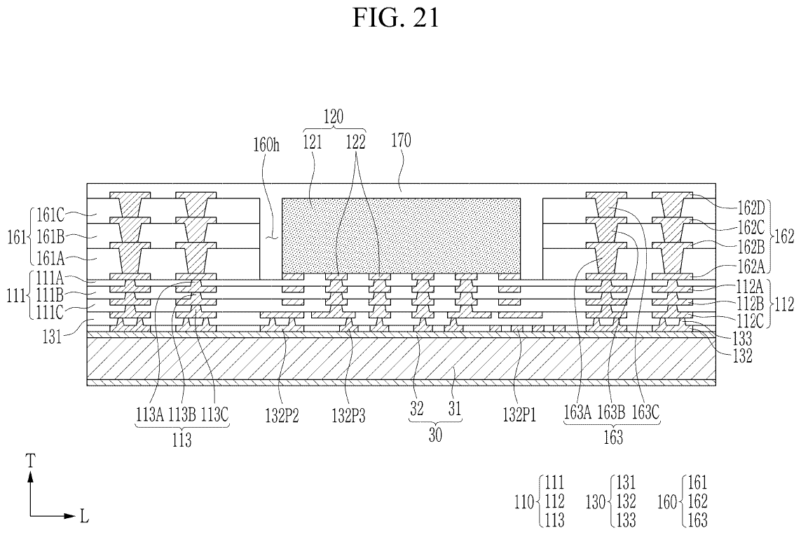

Next, referring to FIG. 20 and FIG. 21, the first carrier film 20 may be removed, and a second carrier film 30 may be attached on the under-bump structure 130. Like the first carrier film 20, the second carrier film 30 may be a copper foil laminate such as a DCF that includes an insulating layer 31 and a metal layer 32 disposed on at least one surface of the insulating layer 31.

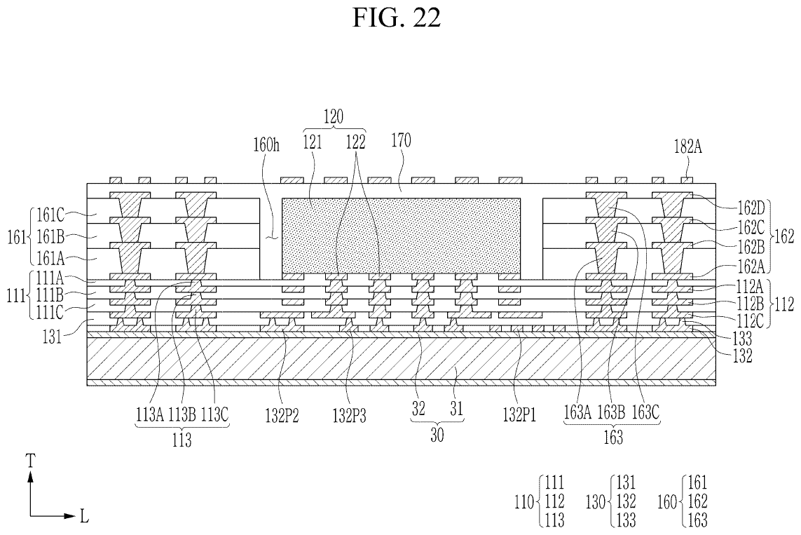

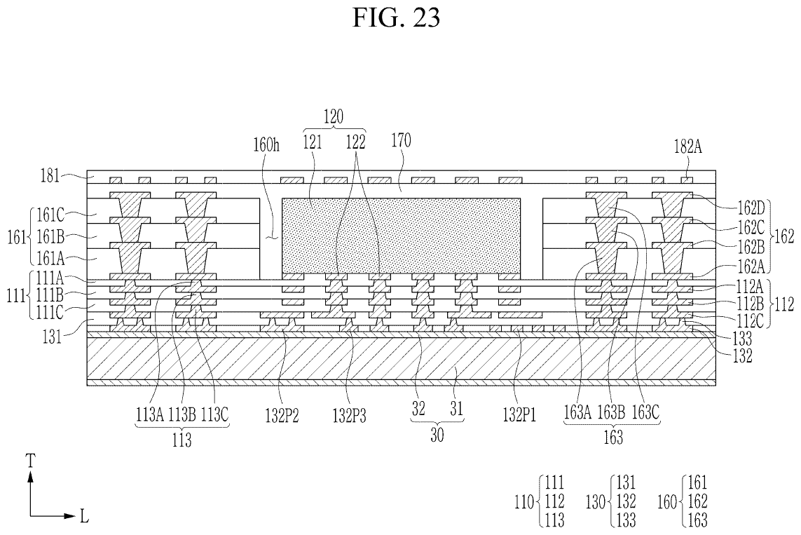

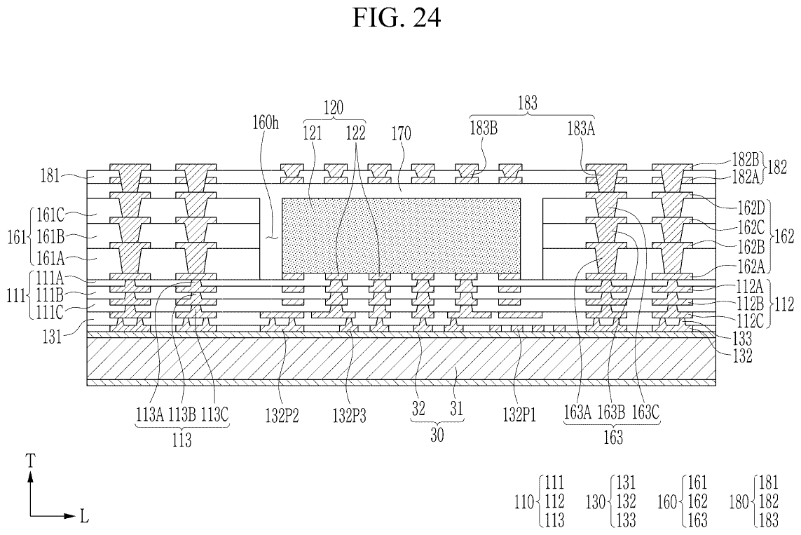

Next, referring to FIGS. 22 to 24, the second redistribution line structure 180 may be formed on the sealant 170. For example, the second redistribution line structure 180 may be formed by forming the first redistribution line layer 182A and the insulating layer 181 on the sealant 170 using a modified semi-additive process (MASP) method, then forming a deep via hole that penetrates the insulating layer 181 and the sealant 170 to expose the fourth wiring layer 162D and a via hole that penetrates the insulating layer 181 to expose the first redistribution line layer 182A, and then forming the via 183 and the second redistribution line layer 182B using a semi-additive process (SAP) method.

For example, an additional metal layer for preventing corrosion and oxidation of the second redistribution line layer 182B and improving reliability may be disposed on the second redistribution line layer 182B. For example, a nickel layer and a metal layer may be disposed on the second redistribution line layer 182B by sequentially plating nickel and gold.

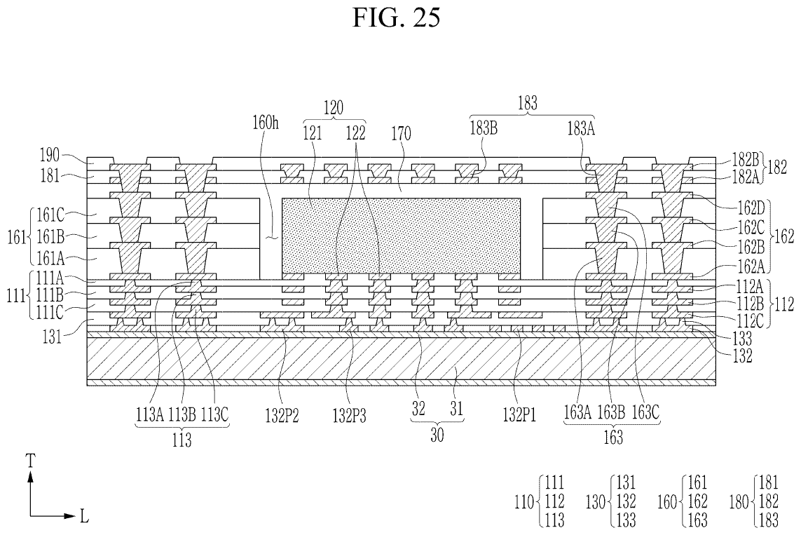

Next, referring to FIG. 25, the second passivation layer 190 may be formed on the second redistribution line structure 180. An opening that exposes at least a portion of the second redistribution line layer 182B may be formed at the second passivation layer 190 through laser processing or the like.

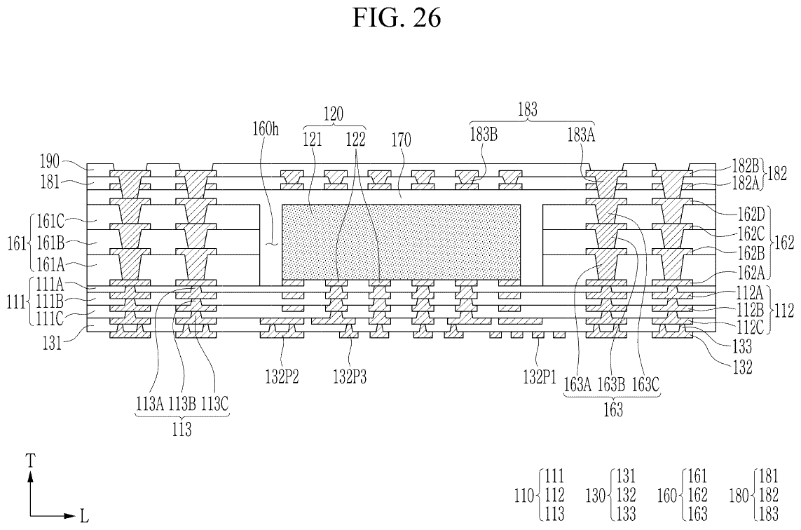

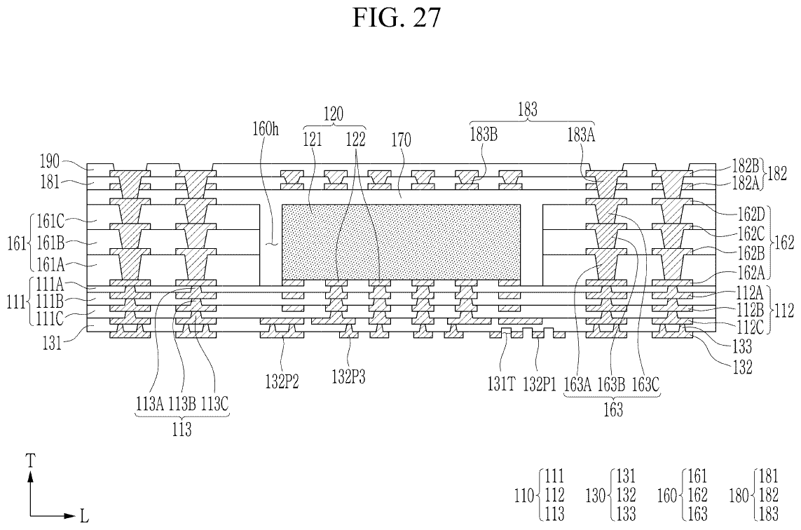

Next, referring to FIG. 26 and FIG. 27, the second carrier film 30 may be removed, and the trench 131T may be formed at the first passivation layer 131. For example, the trench 131T may be formed by laser processing.

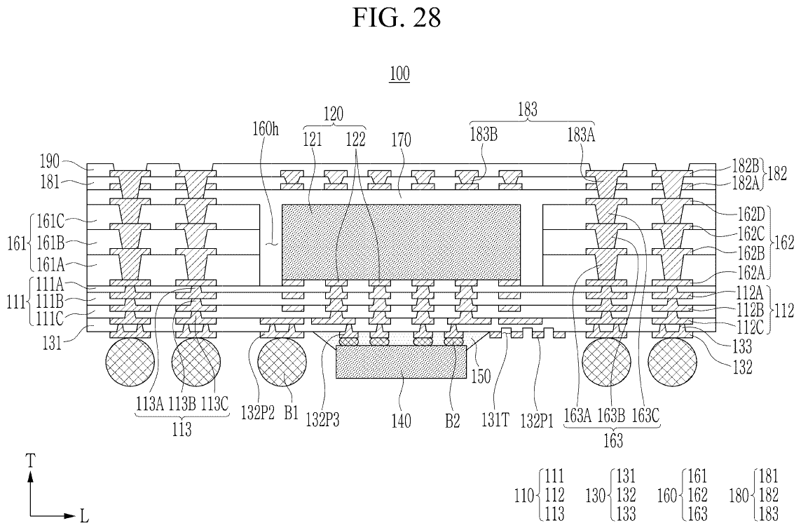

Finally, referring to FIG. 28, the first conductive bump B1 may be attached on the first conductive pad 132P2. After the electronic component 140 is attached above the second conductive pad 132P3 through the second conductive bump B2, the underfill material may be injected between the second conductive pad 132P3 and the electronic component 140 to form the underfill member 150.

While this disclosure has been described in connection with what is presently considered to be practical example embodiments, it is to be understood that the inventive concepts are not limited to the disclosed example embodiments, but, on the contrary, are intended to cover various modifications and equivalent arrangements included within the spirit and scope of the appended claims. Even if content described in some example embodiments of the inventive concepts are not described in some other example embodiments, it may be equally applied to the some other example embodiments.

What is claimed is:

1. A semiconductor package comprising:
a redistribution line structure;
a semiconductor chip on a first surface of the redistribution line structure;
an under-bump structure on a second surface of the redistribution line structure that is opposite the first surface, the under-bump structure including a passivation layer and a conductive pattern layer;
an electronic component above the under-bump structure; and
an underfill member filling a space between the under-bump structure and the electronic component,
wherein the conductive pattern layer is spaced apart from one side surface of the electronic component in plan view, and the conductive pattern layer including a bleeding prevention pattern,
the bleeding prevention pattern including at least one dam region configured to block bleeding of the underfill member from the one side surface of the electronic component, and the passivation layer defining at least one trench therein adjacent to the at least one dam region.

2. The semiconductor package of claim 1, wherein the at least one dam region includes a plurality of dam regions spaced apart from each other in a direction away from the one side surface of the electronic component, and the at least one trench is a single trench including regions respectively positioned between the plurality of dam regions.

3. The semiconductor package of claim 1, wherein the at least one dam region includes a plurality of dam regions spaced apart from each other in a direction away from the one side surface of the electronic component, and the at least one trench comprises a plurality of trenches respectively positioned between the plurality of dam regions.

4. The semiconductor package of claim 1, wherein the at least one dam region comprises a plurality of dam regions, and the plurality of dam regions includes a first dam region closest to the electronic component from among the plurality of dam regions, and
the passivation layer includes a region exposed through the bleeding prevention pattern, the region of the passivation layer extending from a region adjacent to the one side surface of the electronic component to a trench of the at least one trench that is adjacent to the first dam region in plan view.

5. The semiconductor package of claim 1, wherein a length of a dam region of the at least one dam region is 1 μm or more and 10 μm or less, and the length being along a direction toward the dam region from the one side surface of the electronic component.

6. The semiconductor package of claim 4, wherein a length of the trench of the at least one trench between the plurality of dam regions is 1 μm or more and 10 μm or less, and the length being along a direction toward the plurality of dam regions from the one side surface of the electronic component.

7. The semiconductor package of claim 1, wherein a depth of the at least one trench is 1 μm or more and 10 μm or less.

8. The semiconductor package of claim 1, wherein a thickness of the bleeding prevention pattern is 1 μm or more and 15 μm or less.

9. The semiconductor package of claim 1, wherein the conductive pattern layer further includes a first conductive pad and a second conductive pad, the electronic component is above the first conductive pad, and the semiconductor package further comprises a first conductive bump on the second conductive pad.

10. The semiconductor package of claim 9, wherein the first conductive pad, the second conductive pad, and the bleeding prevention pattern are at a same level on the passivation layer.

11. The semiconductor package of claim 9, further comprising a second conductive bump between the first conductive pad and the electronic component, the second conductive bump being covered with the underfill member.

12. The semiconductor package of claim 1, wherein the bleeding prevention pattern includes a first metal layer, and a second metal layer on the first metal layer.

13. The semiconductor package of claim 1, wherein the electronic component is an integrated stacked capacitor (ISC).

14. A semiconductor package comprising:
a redistribution line structure;
a semiconductor chip on a first surface of the redistribution line structure;
an under-bump structure on a second surface of the redistribution line structure opposite the first surface, the under-bump structure including a passivation layer and a conductive pattern layer;
an electronic component above the under-bump structure; and
an underfill member filling a space between the under-bump structure and the electronic component,
wherein the conductive pattern layer includes a bleeding prevention pattern surrounding the electronic component, the bleeding prevention pattern including a plurality of dam regions spaced apart from each other along a direction extending away from one side surface of the electronic component in plan view, and
wherein the plurality of dam regions are at a region adjacent the one side surface of the electronic component, the plurality of dam regions are configured to block bleeding of the underfill member from the one side surface of the electronic component, and the passivation layer defines at least one trench therein between the plurality of dam regions.

15. The semiconductor package of claim 14, wherein the at least one trench is a single trench including regions respectively positioned between the plurality of dam regions.

16. The semiconductor package of claim 14, wherein the at least one trench comprises a plurality of trenches respectively positioned between the plurality of dam regions.

17. The semiconductor package of claim 14, wherein the plurality of dam regions includes a first dam region closest to the electronic component from among the plurality of dam regions, and
the passivation layer includes a region exposed through the bleeding prevention pattern, the region of the passivation layer extending from a region adjacent to the one side surface of the electronic component to a trench of the at least one trench that is adjacent to the first dam region in plan view.

18. A semiconductor package comprising:
a redistribution line structure;
a semiconductor chip on a first surface of the redistribution line structure;
an under-bump structure on a second surface of the redistribution line structure that is opposite the first surface, the under-bump structure including a passivation layer and a conductive pattern layer,
the conductive pattern layer including a bleeding prevention pattern, at least one first conductive pad, and second conductive pads;
an electronic component above the at least one first conductive pad;
an underfill member filling a space between the at least one first conductive pad and the electronic component; and
conductive bumps on the second conductive pads,
wherein the bleeding prevention pattern is at a region adjacent to one side surface of the electronic component, the second conductive pads are at regions adjacent to remaining side surfaces of the electronic component other than the one side surface, and the passivation layer defines a trench therein adjacent to the bleeding prevention pattern in plan view.

19. The semiconductor package of claim 18, wherein the bleeding prevention pattern includes at least one dam region configured to block bleeding of the underfill member from the one side surface of the electronic component, and the trench is adjacent to the at least one dam region.

20. The semiconductor package of claim 18, wherein the at least one first conductive pad, the second conductive pads, and the bleeding prevention pattern are at a same level on the passivation layer.
